(19) United States
(12) Patent Application Publication
(10) Pub. No.: US 2026/0184869 A1
(43) Pub. Date: Jul. 2, 2026

(54) PREPREG, LAMINATED PLATE, PRINTED WIRING BOARD, AND SEMICONDUCTOR PACKAGE

(71) Applicant: Resonac Corporation, Minato-ku, Tokyo (JP)

(72) Inventors: Yuzuru KOBAYASHI, Minato-ku, Tokyo (JP); Tomohiko KOTAKE, Minato-ku, Tokyo (JP)

(21) Appl. No.: 18/855,735

(22) PCT Filed: Oct. 6, 2022
(86) PCT No.: PCT/JP2022/037428

§ 371 Date: Oct. 10, 2024

(51) Int. Cl. C08J 5/24; H10W 70/695

(52) U.S. Cl. CPC C08J 5/244; C08J 5/249; H10W 70/695; C08J 2363/00

(57) ABSTRACT

The present invention relates to a prepreg containing a thermosetting resin composition and a fiber base material, in which the prepreg has one surface and other surface opposite to the one surface, and in a direction from at least any surface of the one surface and the other surface as a starting point toward the surface opposite to the surface serving as the starting point, the prepreg has, in the following order, a first region that configures the surface of the prepreg serving as the starting point and is a region containing a thermosetting resin composition, and a second region that is a region containing a thermosetting resin composition different from the thermosetting resin composition contained in the first region, and a storage elastic modulus E′(1) at 260° C. of a cured product of the thermosetting resin composition contained in the first region is lower than a storage elastic modulus E′(2) at 260° C. of a cured product of the thermosetting resin composition contained in the second region.

### TECHNICAL FIELD

The present embodiment relates to a prepreg, a laminated plate, a printed wiring board, and a semiconductor package.

### BACKGROUND ART

In recent years, with the flow of miniaturization and high performance of electronic devices, an increase in the wiring density and higher integration have been in progress in printed wiring boards.

Thermosetting resins are mainly used as the insulating materials of the printed wiring boards. Thermosetting resins have excellent insulating properties and heat resistance, but have a higher coefficient of thermal expansion than inorganic members such as semiconductor elements and circuits, and thus have a problem of the occurrence of warpage attributed to the difference in coefficient of thermal expansion from inorganic members in some cases.

When a semiconductor chip is mounted on the surface of a printed wiring board, the difference between the warpage amount of a semiconductor package at room temperature and the warpage amount at a reflow temperature (hereinafter, also referred to as “warpage change amount”) is increased due to the difference in coefficient of thermal expansion. Such an increase in the warpage change amount is a factor that degrades the connection reliability of semiconductor packages.

As a method for reducing the coefficient of thermal expansion of an insulating material, for example, a method for highly filling a thermosetting resin with an inorganic filler has been proposed (for example, see PTL 1). By highly filling the thermosetting resin with the inorganic filler having a small coefficient of thermal expansion, the difference in coefficient of thermal expansion between an insulating material containing the thermosetting resin and an inorganic member such as a semiconductor element can be reduced.

### CITATION LIST

### Patent Literature

PTL 1: JP-A-2020-059820

### SUMMARY OF INVENTION

### Technical Problem

However, high filling with the inorganic filler may cause a deterioration in adhesiveness between an insulating material and a conductor layer (hereinafter, also referred to as “conductor adhesion”). Therefore, the method for improving warpage by the high filling with an inorganic filler has a limit from the viewpoint of maintaining good balance with the conductor adhesion.

In view of such circumstances, an object of the present embodiment is to provide a prepreg capable of reducing the warpage change amount of a semiconductor package and having good conductor adhesion, a laminated plate, a printed wiring board, and a semiconductor package in which the prepreg is used.

### Solution to Problem

As a result of repeating intensive studies to solve the above-described problem, the present inventors have found that the above-described problem can be solved by the present embodiment described below.

That is, the present embodiment relates to the following [1] to [12].

[1] A prepreg containing a thermosetting resin composition and a fiber base material,
in which the prepreg has one surface and other surface opposite to the one surface,
in a direction from at least any surface of the one surface and the other surface as a starting point toward the surface opposite to the surface serving as the starting point, the prepreg has, in the following order,
   a first region that configures the surface of the prepreg serving as the starting point and is a region containing a thermosetting resin composition, and
   a second region that is a region containing a thermosetting resin composition different from the thermosetting resin composition contained in the first region, and
a storage elastic modulus E′(1) at 260° C. of a cured product of the thermosetting resin composition contained in the first region is lower than a storage elastic modulus E′(2) at 260° C. of a cured product of the thermosetting resin composition contained in the second region.

[2] The prepreg according to [1], in which, in a direction from each of the one surface and the other surface as a starting point toward a surface opposite to the surface serving as the starting point, the prepreg has the first region and the second region in this order.

[3] The prepreg according to [1] or [2], in which a difference [E′(2)−E′(1)] between the storage elastic modulus E′(1) at 260° C. of the cured product of the thermosetting resin composition contained in the first region and the storage elastic modulus E′(2) at 260° C. of the cured product of the thermosetting resin composition contained in the second region is 0.05 to 1.5 GPa.

[4] The prepreg according to any one of [1] to [3], in which the storage elastic modulus E′(1) at 260° C. of the cured product of the thermosetting resin composition contained in the first region is 0.1 to 1.5 GPa.

[5] The prepreg according to any one of [1] to [4], in which the storage elastic modulus E′(2) at 260° C. of the cured product of the thermosetting resin composition contained in the second region is 0.5 to 2.0 GPa.

[6] The prepreg according to any one of [1] to [5], in which the thermosetting resin composition contained in the first region and the thermosetting resin composition contained in
the second region contain an inorganic filler, and a volume-based content V(1) of the inorganic filler in the thermosetting resin composition contained in the first region is lower than a volume-based content V(2) of the inorganic filler in the thermosetting resin composition contained in the second region.

[7] The prepreg according to [6], in which a difference [V(2)−V(1)] between the volume-based content V(1) of the inorganic filler in the thermosetting resin composition contained in the first region and the volume-based content V(2) of the inorganic filler in the thermosetting resin composition contained in the second region is 2% to 40% by volume.

[8] The prepreg according to any one of [1] to [7], in which the volume-based content V(1) of the inorganic filler in the thermosetting resin composition contained in the first region is 5% to 60% by volume.

[9] The prepreg according to any one of [1] to [8], in which the volume-based content V(2) of the inorganic filler in the thermosetting resin composition contained in the second region is 20% to 80% by volume.

[10] A laminated plate including a cured product of the prepreg according to any one of [1] to [9], and a metal foil.

[11] A printed wiring board including a cured product of the prepreg according to any one of [1] to [9].

[12] A semiconductor package including the printed wiring board according to [11], and a semiconductor element.

### Advantageous Effects of Invention

According to the present embodiment, it is possible to provide a prepreg capable of reducing the warpage change amount of a semiconductor package and having good conductor adhesion, a laminated plate, a printed wiring board, and a semiconductor package in which the prepreg is used.

### BRIEF DESCRIPTION OF DRAWINGS

FIG. 1 is a schematic cross-sectional view showing an example of a prepreg of the present embodiment.

FIG. 2 is a schematic cross-sectional view showing another example of the prepreg of the present embodiment.

FIG. 3 is a schematic cross-sectional view showing another example of the prepreg of the present embodiment.

FIG. 4 is a schematic cross-sectional view showing another example of the prepreg of the present embodiment.

FIG. 5 is a schematic cross-sectional view showing another example of the prepreg of the present embodiment.

FIG. 6 is a schematic cross-sectional view showing another example of the prepreg of the present embodiment.

FIG. 7 is a schematic cross-sectional view showing another example of the prepreg of the present embodiment.

FIG. 8 is a schematic cross-sectional view for describing the configuration of a prepreg in an example.

### DESCRIPTION OF EMBODIMENTS

In the present description, a numerical range indicated by using “to” indicates a range including numerical values described before and after “to” as a minimum value and a maximum value, respectively.

For example, the expression of a numerical range “X to Y” (X and Y are real numbers) means a numerical range that is X or more and Y or less. Further, the expression of “X or more” in the present description herein means X and a numerical value exceeding X. Furthermore, the expression of “Y or less” in the present description herein means Y and a numerical value less than Y.

The lower limit value and the upper limit value of a numerical range described in the present description can be arbitrarily combined with the lower limit value or the upper limit value of another numerical range, respectively.

In a numerical range described in the present description, the lower limit value or the upper limit value of the numerical range may be replaced with a value shown in Examples.

Each component and material exemplified in the present description may be used alone or may be used in combination of two or more kinds thereof, unless particularly otherwise specified.

In the present description, when a plurality of substances corresponding to each component are present in a resin composition, the content of each component in the resin composition means the total amount of the plurality of substances present in the resin composition, unless particularly otherwise specified.

In the present description, the “solid content” means a component other than a solvent, and includes a liquid state, a starch syrup state, and a wax state at room temperature. In the present description, the room temperature indicates 25° C.

In the present description, the “semi-cured product” has the same meaning as a resin composition in a B-stage state in JIS K 6800 (1985), and the “cured product” has the same meaning as a resin composition in a C-stage state in JIS K 6800 (1985).

The action mechanism described in the present description is a conjecture, and does not limit the mechanism by which the effect of the present embodiment is exhibited.

An aspect in which the matters described in the present description are arbitrarily combined is also included in the present embodiment.

### [Prepreg]

A prepreg of the present embodiment is a prepreg containing a thermosetting resin composition and a fiber base material,
in which the prepreg has one surface and other surface opposite to the one surface,
in a direction from at least any surface of the one surface and the other surface as a starting point toward the surface opposite to the surface serving as the starting point, the prepreg has, in the following order,
   a first region that configures the surface of the prepreg serving as the starting point and is a region containing the thermosetting resin composition, and
   a second region that is a region containing a thermosetting resin composition different from the thermosetting resin composition contained in the first region, and
a storage elastic modulus E′(1) at 260° C. of a cured product of the thermosetting resin composition contained in the first region is lower than a storage elastic modulus E′(2) at 260° C. of a cured product of the thermosetting resin composition contained in the second region.

The reason why the prepreg of the present embodiment can reduce the warpage change amount of a semiconductor package and has good conductor adhesion is not clear, but is presumed as follows.

The prepreg of the present embodiment has a first region containing a thermosetting resin composition in which the storage elastic modulus E′ at 260° C. (hereinafter, also referred to as “260° C. storage elastic modulus E′”) of a cured product is relatively low and a second region containing a thermosetting resin composition in which the 260° C. storage elastic modulus E′ of a cured product is relatively high in order in a direction from at least one surface as a starting point toward the surface opposite to the surface serving as the starting point.

It is considered that the cured product of the thermosetting resin composition contained in the first region has a low 260° C. storage elastic modulus E′ and thus relaxes stress attributed to the difference in coefficient of thermal expansion from an inorganic member such as a semiconductor chip mounted on the cured product in the first region. Further, it is presumed that, since the 260° C. storage elastic modulus E′ of the thermosetting resin composition contained in the second region is high, the cured product in the second region increases the rigidity of a cured product of the prepreg, thereby reducing the warpage change amount of the semiconductor package. That is, it is considered that, as described above, the prepreg of the present embodiment can reduce the warpage change amount due to the stress relaxation property and the rigidity even without being highly filled with an inorganic filler, and thus the conductor adhesion can be favorably maintained.

The prepreg of the present embodiment may have the first region and the second region in this order in a direction from at least any surface of the one surface and the other surface as a starting point toward the surface opposite to the surface serving as the starting point, and preferably have the first region and the second region in this order in a direction from each of the one surface and the other surface as a starting point toward the surface opposite to the surface serving as the starting point.

Hereinafter, the form of the prepreg of the present embodiment will be described in detail with reference to the drawings.

### <Form of Prepreg>

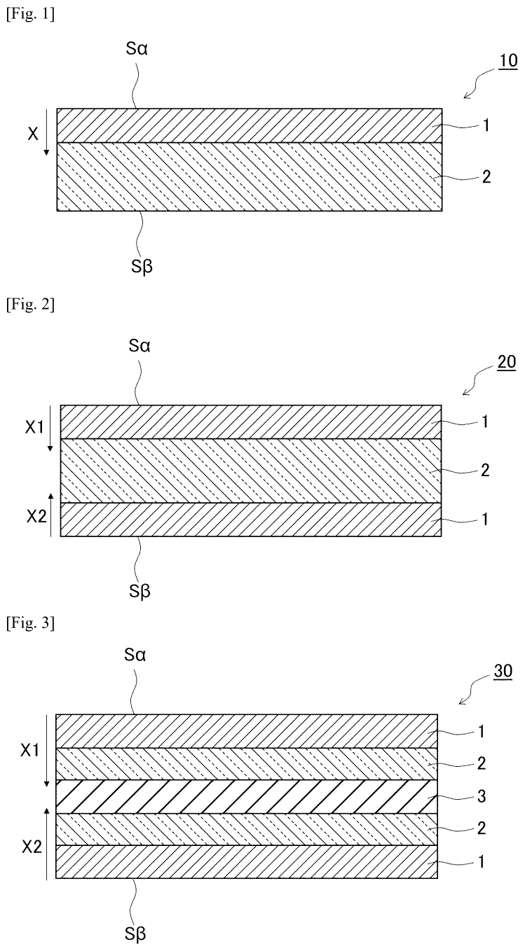

Examples of the form of the prepreg of the present embodiment include the forms of prepregs 10, 20, and 30 shown in FIGS. 1 to 3. In FIGS. 1 to 3, fiber base materials are not shown.

A prepreg 10 of the first embodiment shown in FIG. 1 has a first region 1 and a second region 2 in this order in a direction X from one surface Sα as a starting point toward the other surface Sβ.

The first region 1 configures the one surface Sα of the prepreg 10, and the second region 2 configures the other surface Sβ of the prepreg 10.

The first region and the second region in the prepreg of the present embodiment, for example, preferably form layers like the prepreg 10 shown in FIG. 1. There is no clear interface between adjacent layers, and for example, a part of the configuration component of the first region and a part of the configuration component of the second region may be in a compatible or mixed state.

A prepreg 20 of the second embodiment shown in FIG. 2 has a first region 1 and a second region 2 in this order in a direction X1 from one surface Sα as a starting point toward the other surface Sβ and has another first region 1 and the second region 2 in this order in a direction X2 from the other surface Sβ as a starting point toward the one surface Sα. In other words, the prepreg 20 has the first region 1, the second region 2, and the first region 1 in this order.

In the prepreg 20, the first regions 1 configure the one surface Sα and the other surface Sβ of the prepreg 20, respectively.

A prepreg 30 of the third embodiment shown in FIG. 3 has a first region 1, a second region 2, and a third region 3 in this order in a direction X1 from one surface Sα as a starting point toward the other surface Sβ and has another first region 1, another second region 2, and the third region 3 in this order in a direction X2 from the other surface Sβ as a starting point toward the one surface Sα. In other words, the prepreg 30 has the first region 1, the second region 2, the third region 3, the second region 2, and the first region 1 in this order.

In the prepreg 30, the first regions 1 configure the one surface Sa and the other surface SB of the prepreg 30, respectively.

The third region 3 is a region containing a third thermosetting resin composition, and the storage elastic modulus E′ at 260° C. of a cured product of the third thermosetting resin composition is lower than the storage elastic modulus E′(2) at 260° C. of a cured product of the thermosetting resin composition contained in the second region contained in the second region 2.

The prepreg of the present embodiment, like the prepreg 20 shown in FIG. 2 or the prepreg 30 shown in FIG. 3, preferably has the first region and the second region in this order in the direction from each of the one surface and the other surface as the starting point toward the surface opposite to the surface serving as the starting point.

For example, when the prepreg of the present embodiment has two or more first regions like the prepreg 20 shown in FIG. 2 and the prepreg 30 shown in FIG. 3, the composition and thickness of the two or more first regions may be the same as or different from each other.

For example, when the prepreg of the present embodiment has two or more second regions like the prepreg 30 shown in FIG. 3, the composition and thickness of the two or more second regions may be the same as or different from each other.

In the following description, regarding a suitable aspect of the first region relating to various storage elastic moduli, thicknesses, and compositions, when the prepreg of the present embodiment has two or more first regions, all of the first regions are preferably the suitable aspect, and among two or more first regions, only a part of the first regions may be the suitable aspect.

Similarly, in the following description, regarding a suitable aspect of the second region relating to various storage elastic moduli, thicknesses, and compositions, when the prepreg of the present embodiment has two or more second regions, all of the second regions are preferably the suitable aspect, and among two or more second regions, only a part of the second regions may be the suitable aspect. This is also true when the prepreg of the present embodiment has two or more third regions.

### <Position of Fiber Base Material in Prepreg>

In the prepreg of the present embodiment, the position of the fiber base material is not particularly limited, and the fiber base material is preferably contained in the second region.

That is, the second region is preferably a region containing the thermosetting resin composition and the fiber base material. In this case, the fiber base material may be partially contained in the second region or may be wholly contained in the second region.

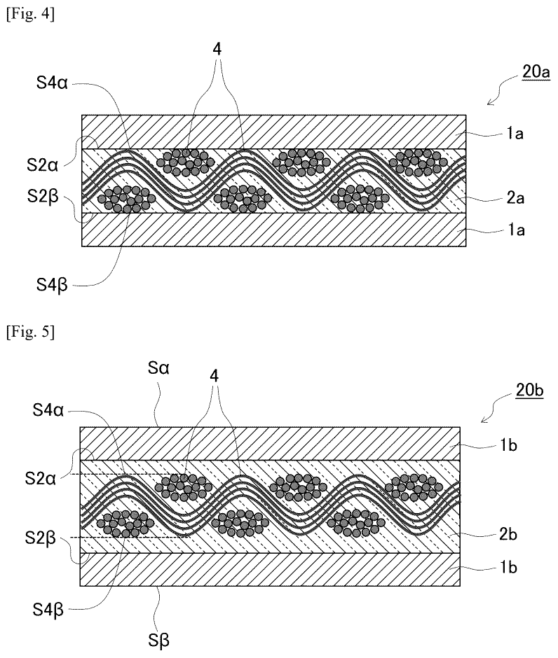

FIG. 4 and FIG. 5 are schematic cross-sectional views showing the fiber base material in the prepreg 20 of the second embodiment.

In a prepreg 20a shown in FIG. 4, a fiber base material 4 is contained in a second region 2a, and in a cross-sectional view, one surface S4α of the fiber base material 4 substantially coincides with one surface S2α of the second region 2a, and the other surface S4β of the fiber base material 4 substantially coincides with the other surface S2β of the second region 2a.

In other words, the prepreg 20a shown in FIG. 4 has, in a cross-sectional view, a composite layer 2a containing the thermosetting resin composition contained in the second region and the fiber base material 4, and a resin layer 1a containing the thermosetting resin composition contained in the first region, but not containing the fiber base material on each of both sides of the composite layer 2a. The composite layer 2a corresponds to the second region, and the resin layer 1a corresponds to the first region.

A prepreg 20b shown in FIG. 5 contains a fiber base material 4 in a second region 2b.

In the prepreg 20b, a surface S2α of the second region 2b on one surface Sa side of the prepreg 20b is present at a position closer to the one surface Sα of the prepreg 20b than a surface S4α of the fiber base material 4 on the one surface Sα side.

In addition, in the prepreg 20b, a surface S2β of the second region 2b on another surface Sβ side of the prepreg 20b is present at a position closer to the other surface Sβ of the prepreg 20b than a surface S4β of the fiber base material 4 on the other surface Sβ side.

In other words, the prepreg 20b shown in FIG. 5 has, in a cross-sectional view, resin layers 1b containing the thermosetting resin composition contained in the first region, but not containing the fiber base material on both sides of the composite layer 2b containing the thermosetting resin composition contained in the second region and the fiber base material 4.

The composite layer 2b corresponds to the second region, and the resin layer 1b corresponds to the first region.

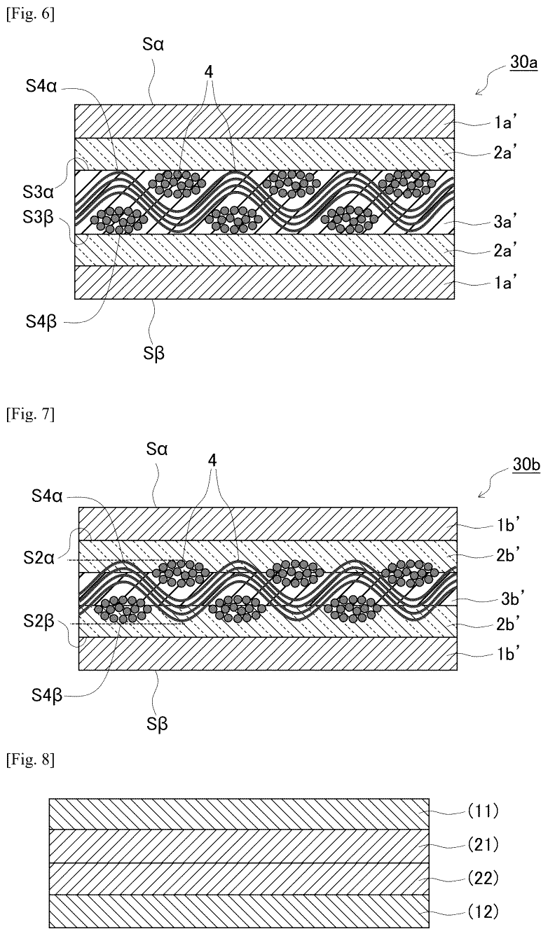

FIG. 6 and FIG. 7 are schematic cross-sectional views showing the fiber base material in the prepreg 30 of the third embodiment.

In a prepreg 30a shown in FIG. 6, a fiber base material 4 is contained in a third region 3a′, and in a cross-sectional view, one surface S4α of the fiber base material 4 substantially coincides with one surface S3α of the third region 3a′, and other surface S4β of the fiber base material 4 substantially coincides with the other surface S3β of the third region 3a′.

In other words, the prepreg 30a shown in FIG. 6 has, in a cross-sectional view, a second resin layer 2a′ containing the thermosetting resin composition contained in the second region, but not containing the fiber base material, and a first resin layer 1a′ containing the thermosetting resin composition contained in the first region, but not containing the fiber base material in this order from the surface of a composite layer 3a′ as a starting point on each of both sides of the composite layer 3a′ containing the third thermosetting resin composition and the fiber base material 4.

The composite layer 3a′ corresponds to the third region, the first resin layer 1a′ corresponds to the first region, and the second resin layer 2a′ corresponds to the second region.

A prepreg 30b shown in FIG. 7 contains a fiber base material 4 in a second region 2b′ and a third region 3b′.

In the prepreg 30b, a surface S2α of the second region 2b on one surface Sα side of the prepreg 30b is present at a position closer to the one surface Sa of the prepreg 30b than a surface S4α of the fiber base material 4 on the one surface Sα side.

In addition, in the prepreg 30b, a surface S2β of the second region 2b′ on other surface Sβ side of the prepreg 30b is present at a position closer to the other surface Sβ of the prepreg 30b than a surface S4β of the fiber base material 4 on the other surface Sβ side.

In other words, the prepreg 30b shown in FIG. 7 has, in a cross-sectional view, a second composite layer 2b′ containing the thermosetting resin composition contained in the second region and the fiber base material, and a resin layer 1b′ containing the thermosetting resin composition contained in the first region, but not containing the fiber base material in this order from the surface of a first composite layer 3b′ as a starting point on each of both sides of the first composite layer 3b′ containing the third thermosetting resin composition and the fiber base material 4.

The first composite layer 3b′ corresponds to the third region, the second composite layer 2b′ corresponds to the second region, and the resin layer 1b′ corresponds to the first region.

### <Thickness of Prepreg>

The thickness of the prepreg of the present embodiment is not particularly limited and may be appropriately determined depending on the use, and is preferably 20 to 200 μm, more preferably 30 to 150 μm, and still more preferably 40 to 100 μm.

### <Storage Elastic Modulus E′ at 40° C. of Cured Product of Prepreg>

The storage elastic modulus E′ at 40° C. of the cured product of the prepreg of the present embodiment (hereinafter, also referred to as “40° C. storage elastic modulus E′”) is not particularly limited, and is preferably 5 to 30 GPa, more preferably 8 to 20 GPa, and still more preferably 10 to 15 GPa from the viewpoint of further improving the warpage change amount and the conductor adhesion of the semiconductor package.

The 40° C. storage elastic modulus E′ of the cured product of the prepreg can be measured by the method described in Examples.

### <Thickness of Each Region>

The thickness of the first region is not particularly limited, and is preferably 5 to 70 μm, more preferably 6 to 50 μm, and still more preferably 7 to 30 μm from the viewpoint of further improving the warpage change amount and the conductor adhesion of the semiconductor package.

The thickness of the second region is not particularly limited, and is preferably from 5 to 150 μm, more preferably from 10 to 100 μm, and still more preferably from 15 to 50 μm from the viewpoint of further improving the warpage change amount and the conductor adhesion of the semiconductor package.

When the prepreg of the present embodiment has the third region, the thickness of the third region is not particularly limited, and is preferably from 5 to 150 μm, more preferably from 10 to 100 μm, and still more preferably from 15 to 50 μm from the viewpoint of further improving the warpage change amount and the conductor adhesion of the semiconductor package.

The total volume of the first region in the prepreg of the present embodiment is not particularly limited, and is preferably 10% to 80% by volume, more preferably 20% to 70% by volume, and still more preferably 30% to 60% by volume, with respect to the entire prepreg of the present embodiment, from the viewpoint of further improving the warpage change amount and the conductor adhesion of the semiconductor package.

The total volume of the second region in the prepreg of the present embodiment is not particularly limited, and is preferably 20% to 90% by volume, more preferably 30% to 80% by volume, and still more preferably 40% to 70% by volume, with respect to the entire prepreg of the present embodiment, from the viewpoint of further improving the warpage change amount and the conductor adhesion of the semiconductor package.

The total volume of the first region and the second region in the prepreg of the present embodiment is not particularly limited, and is preferably 60% to 100% by volume, more preferably 80% to 100% by volume, and still more preferably 95% to 100% by volume, with respect to the entire prepreg of the present embodiment.

### <Storage Elastic Modulus of Each Thermosetting Resin Composition>

The 260° C. storage elastic modulus E′(1) of the cured product of the thermosetting resin composition contained in the first region is not particularly limited, and is preferably 0.1 to 1.5 GPa, more preferably 0.3 to 1.0 GPa, and still more preferably 0.5 to 0.7 GPa from the viewpoint of further improving the warpage change amount and the conductor adhesion of the semiconductor package.

The 260° C. storage elastic modulus E′(2) of the cured product of the thermosetting resin composition contained in the second region is not particularly limited, and is preferably 0.5 to 2.0 GPa, more preferably 0.8 to 1.3 GPa, and still more preferably 1.0 to 1.2 GPa from the viewpoint of further improving the warpage change amount and the conductor adhesion of the semiconductor package.

The difference [E′(2)−E′(1)] between the storage elastic modulus E′(1) at 260° C. of the cured product of the thermosetting resin composition contained in the first region and the storage elastic modulus E′(2) at 260° C. of the cured product of the thermosetting resin composition contained in the second region is not particularly limited, and is preferably 0.05 to 1.5 GPa, more preferably 0.2 to 1.0 GPa, and still more preferably 0.4 to 0.6 GPa from the viewpoint of further improving the warpage change amount and the conductor adhesion of the semiconductor package.

The 260° C. storage elastic moduli E′ of the cured products of the thermosetting resin composition contained in the first region and the thermosetting resin composition contained in the second region can be measured by the method described in Examples.

The 40° C. storage elastic modulus E′ of the cured product of the thermosetting resin composition contained in the first region is not particularly limited, and is preferably 2 to 10 GPa, more preferably 3 to 8 GPa, and still more preferably 4 to 6 GPa from the viewpoint of further improving the warpage change amount and the conductor adhesion of the semiconductor package.

The 40° C. storage elastic modulus E′ of the cured product of the thermosetting resin composition contained in the second region is not particularly limited, and is preferably 3 to 12 GPa, more preferably 4 to 10 GPa, and still more preferably 5 to 7 GPa from the viewpoint of further improving the warpage change amount and the conductor adhesion of the semiconductor package.

The difference [the 40° C. storage elastic modulus E′ of the cured product of the thermosetting resin composition contained in the second region−the 40° C. storage elastic modulus E′ of the cured product of the thermosetting resin composition contained in the first region] between the 40° C. storage elastic modulus E′ of the cured product of the thermosetting resin composition contained in the first region and the 40° C. storage elastic modulus E′ of the cured product of the thermosetting resin composition contained in the second region is not particularly limited, and is preferably 0.1 to 5 GPa, more preferably 0.5 to 3 GPa, and still more preferably 0.8 to 1.5 GPa from the viewpoint of further improving the warpage change amount and the conductor adhesion of the semiconductor package.

The 40° C. storage elastic moduli E′ of the cured products of the thermosetting resin composition contained in the first region and the thermosetting resin composition contained in the second region can be measured by the method described in Examples.

When the prepreg of the present embodiment has the third region, preferable ranges of the 260° C. storage elastic modulus E′ and the 40° C. storage elastic modulus E′ of the cured product of the third thermosetting resin composition are the same as the preferable ranges of the 260° C. storage elastic modulus E′ and the 40° C. storage elastic modulus E′ of the cured product of the thermosetting resin composition contained in the first region.

### <Composition of Each Thermosetting Resin Composition>

Next, the composition of each thermosetting resin composition will be described below. In the following description, unless particularly otherwise specified, when described simply as the “thermosetting resin composition”, it refers to all of the thermosetting resin composition contained in the first region, the thermosetting resin composition contained in the second region, and the third thermosetting resin composition that is contained as necessary.

The thermosetting resin composition contains at least a thermosetting resin.

In addition to the thermosetting resin, the thermosetting resin composition preferably contains, for example, at least one selected from the group consisting of an inorganic filler, a curing agent, a curing accelerator, an organic filler, a coupling agent, a leveling agent, an antioxidant, a flame retardant, a flame retardant aid, a thixotropic agent, a thickener, a flexible material, a surfactant, and a photopolymerization initiator, and more preferably contains an inorganic filler and a curing accelerator.

Hereinafter, each component that can be contained in the thermosetting resin composition will be described.

Each component may be used alone, or two or more kinds may be used in combination, for each.

### (Thermosetting Resin)

Examples of the thermosetting resin include an epoxy resin, a polyimide resin, a maleimide resin, a modified maleimide resin, a phenol resin, a polyphenylene ether resin, a bismaleimide-triazine resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin.

Among these, a maleimide resin, a modified maleimide resin, an epoxy resin, a polyimide resin, a cyanate resin, a polyphenylene ether resin, a bismaleimide-triazine resin are preferable, and a maleimide resin, a modified maleimide resin, and an epoxy resin are more preferable from the viewpoint of moldability and electrical insulation property.

The maleimide resin is preferably a maleimide resin having one or more N-substituted maleimide groups and more preferably a maleimide resin having two or more N-substituted maleimide groups.

In addition, the maleimide resin is preferably an aromatic maleimide resin having an N-substituted maleimide group directly bonded to an aromatic ring.

Examples of the maleimide resin include aromatic bismaleimide resins having two N-substituted maleimide groups directly bonded to an aromatic ring such as bis(4-maleimidophenyl)methane, bis(4-maleimidophenyl)ether, bis(4-maleimidophenyl)sulfone, 3,3′-dimethyl-5,5′-diethyl-4,4′-diphenylmethane bismaleimide, 4-methyl-1,3-phenylene bismaleimide, m-phenylene bismaleimide, and 2,2-bis[4-(4-maleimide phenoxy)phenyl]propane; aromatic polymaleimide resins having three or more N-substituted maleimide groups directly bonded to an aromatic ring such as polyphenyl methane maleimide and biphenyl aralkyl type maleimide; maleimide resins having an indane ring skeleton; and aliphatic maleimide resins such as 1,6-bismaleimide-(2,2,4-trimethyl) hexane and pyrophosphate binder type long chain alkyl bismaleimide.

Examples of the modified maleimide resin include aminomaleimide resins having a structure derived from a maleimide resin and a structure derived from a diamine compound.

The diamine compound is preferably a compound having two primary amino groups.

In addition, the diamine compound is preferably an aromatic diamine compound having two primary amino groups directly bonded to an aromatic ring.

Examples of the diamine compound include aromatic diamines having two primary amino groups directly bonded to an aromatic ring such as m-phenylenediamine, p-phenylenediamine, 1,4-bis(4-aminophenoxy)benzene, 4,4′-diaminodiphenylmethane, 3,3′-dimethyl-4,4′-diaminodiphenylmethane, 3,3′-diethyl-4,4′-diaminodiphenylmethane, 2,2-bis[4-(4-aminophenoxy)phenyl] propane, 4,4′-diaminobenzophenone, 4,4′-diaminodiphenyl ether, 3,3′-diaminodiphenyl sulfone, 4,4′-diaminodiphenyl sulfone, bis[4-(4-aminophenoxy)phenyl] sulfone, benzidine, 4,4′-bis(4-aminophenoxy) biphenyl, 4,4′-diaminodiphenyl sulfide, and 4,4′-diamino-3,3′-biphenyl diol; and siloxane compounds having two primary amino groups. Among these, 3,3′-dimethyl-4,4′-diaminodiphenylmethane and a siloxane compound having two primary amino groups are preferable.

The siloxane compound having two primary amino groups is preferably a siloxane compound having primary amino groups at both terminals and more preferably a polydimethyl siloxane compound having primary amino groups at both terminals.

The primary amino group equivalent of the siloxane compound having two primary amino groups is not particularly limited, and is preferably 300 to 2,000 g/mol, more preferably 400 to 1,500 g/mol, and still more preferably 500 to 1,000 g/mol.

The aminomaleimide resin may further have a structure derived from an amine compound having an acidic substituent as necessary.

Examples of the amine compound having an acidic substituent include aminophenols such as o-aminophenol, m-aminophenol, and p-aminophenol; aminobenzoic acids such as p-aminobenzoic acid, m-aminobenzoic acid, and o-aminobenzoic acid; aminobenzenesulfonic acids such as o-aminobenzenesulfonic acid, m-aminobenzenesulfonic acid, and p-aminobenzenesulfonic acid; 3,5-dihydroxyaniline and 3,5-dicarboxyaniline. Among these, aminophenols, aminobenzoic acids, and 3,5-dihydroxyaniline are preferable from the viewpoint of the solubility and the synthesis yield, and m-aminophenol and p-aminophenol are more preferable from the viewpoint of the heat resistance.

The content of the structure derived from the maleimide resin in the aminomaleimide resin is not particularly limited, and is preferably 30 to 95 mass %, more preferably 50 to 90 mass %, and still more preferably 70 to 80 mass %.

The content of the structure derived from the diamine compound in the aminomaleimide resin is not particularly limited, and is preferably 2 to 50 mass %, more preferably 5 to 40 mass %, and still more preferably 10 to 30 mass %.

The content of the structure derived from the amine compound having an acidic substituent in the aminomaleimide resin is not particularly limited, and is preferably 0.1 to 10 mass %, more preferably 0.5 to 7 mass %, and still more preferably 1 to 5 mass %.

The aminomaleimide resin can be produced by reacting the maleimide resin, the diamine compound, and the amine compound having an acidic substituent used as necessary by a known method.

The content of one or more selected from the group consisting of the maleimide resin and the modified maleimide resin in the thermosetting resin is not particularly limited, and is preferably 40 to 98 mass %, more preferably 60 to 95 mass %, and still more preferably 70 to 90 mass %.

The epoxy resin is preferably an epoxy resin having two or more epoxy groups. The epoxy resin is classified into a glycidyl ether type epoxy resin, a glycidyl amine type epoxy resin, and a glycidyl ester type epoxy resin, or the like. Among these, a glycidyl ether type epoxy resin is preferable.

The epoxy resin is also classified into various epoxy resins depending on the difference in the main skeleton.

Specifically, epoxy resins are classified into, for example, bisphenol-based epoxy resins such as bisphenol A type epoxy resin, bisphenol F type epoxy resin, and bisphenol S type epoxy resin; bisphenol-based novolac type epoxy resins such as bisphenol A novolac type epoxy resin and bisphenol F novolac type epoxy resin; novolac type epoxy resins other than the above-mentioned bisphenol-based novolac type epoxy resins, such as phenol novolac type epoxy resin, cresol novolac type epoxy resin, and biphenyl novolac type epoxy resin; phenol aralkyl type epoxy resins; stilbene type epoxy resins; naphthalene skeleton-containing epoxy resins such as naphthol novolac type epoxy resin, naphthol type epoxy resin, naphthol aralkyl type epoxy resin, and naphthylene ether type epoxy resin; biphenyl type epoxy resins; biphenyl aralkyl type epoxy resins; xylylene type epoxy resins; dihydroanthracene type epoxy resins; alicyclic epoxy resins such as saturated dicyclopentadiene type epoxy resins; heterocyclic epoxy resins; spiro ring-containing epoxy resins; cyclohexanedimethanol type epoxy resins; trimethylol type epoxy resins; aliphatic chain epoxy resins; and rubber-modified epoxy resins. Among these, biphenyl aralkyl type epoxy resins are preferable.

The content of the epoxy resin in the thermosetting resin is not particularly limited, and is preferably 2 to 60 mass %, more preferably 5 to 40 mass %, and still more preferably 10 to 30 mass %.

The content of the thermosetting resin in the resin components contained in the thermosetting resin composition is not particularly limited, and is preferably 30 to 100 mass %, more preferably 50 to 100 mass %, and still more preferably 70 to 100 mass % with respect to the total amount of the resin components in the thermosetting resin composition from the viewpoint of the heat resistance and the conductor adhesion.

Here, in the present description, the “resin component” means a resin and a compound which forms a resin by a curing reaction.

The volume-based content of the resin components in the thermosetting resin composition contained in the first region is not particularly limited, and is preferably 40% to 95% by volume, more preferably 50% to 90% by volume, and still more preferably 60% to 80% by volume from the viewpoint of further improving the warpage change amount and the conductor adhesion of the semiconductor package.

The volume-based content of the resin components in the thermosetting resin composition contained in the second region is not particularly limited, and is preferably 20% to 80% by volume, more preferably 30% to 70% by volume, and still more preferably 40% to 60% by volume from the viewpoint of further improving the warpage change amount and the conductor adhesion of the semiconductor package.

### (Inorganic Filler)

The thermosetting resin composition preferably contains an inorganic filler from the viewpoint of further improving the warpage change amount and the conductor adhesion of the semiconductor package.

Examples of the inorganic filler include silica, alumina, titanium oxide, mica, beryllia, barium titanate, potassium titanate, strontium titanate, calcium titanate, aluminum carbonate, magnesium hydroxide, aluminum hydroxide, aluminum silicate, calcium carbonate, calcium silicate, magnesium silicate, silicon nitride, boron nitride, clay, talc, aluminum borate, and silicon carbide. Among these, silica and alumina are preferable from the viewpoint of reducing the coefficient of thermal expansion and reducing the relative permittivity and the dielectric dissipation factor, and silica and aluminum hydroxide are preferable from the viewpoint of the heat resistance.

The inorganic filler may have been surface-treated with a surface treatment agent such as a silane coupling agent.

The average particle diameter (D₅₀) of the inorganic filler is not particularly limited, and is preferably 0.01 to 20 μm, more preferably 0.1 to 10 μm, and still more preferably 0.2 to 1 μm, from the viewpoint of the dispersibility and fine wiring of the inorganic filler.

The average particle diameter (D₅₀) of the inorganic filler in the present description is a particle diameter at a point corresponding to 50% by volume when a cumulative frequency distribution curve based on the particle diameter is obtained with the total volume of the particles as 100%. The average particle diameter of the inorganic filler can be measured by, for example, a particle size distribution analyzer using a laser diffraction scattering method.

Examples of the shape of the inorganic filler include a spherical shape and a crushed shape, and a spherical shape is preferable.

It is preferable that the thermosetting resin composition contained in the first region and the thermosetting resin composition contained in the second region contain an inorganic filler, and the volume-based content V(1) of the inorganic filler in the thermosetting resin composition contained in the first region is lower than the volume-based content V(2) of the inorganic filler in the thermosetting resin composition contained in the second region.

The volume-based content V(1) of the inorganic filler in the thermosetting resin composition contained in the first region is not particularly limited, and is preferably 5% to 60% by volume, more preferably 10% to 50% by volume, and still more preferably 20% to 40% by volume from the viewpoint of further improving the warpage change amount and the conductor adhesion of the semiconductor package.

The volume-based content V(2) of the inorganic filler in the thermosetting resin composition contained in the second region is not particularly limited, and is preferably 20% to 80% by volume, more preferably 30% to 70% by volume, and still more preferably 40% to 60% by volume from the viewpoint of further improving the warpage change amount and the conductor adhesion of the semiconductor package.

The difference [V(2)−V(1)] between the volume-based content V(1) of the inorganic filler in the thermosetting resin composition contained in the first region and the volume-based content V(2) of the inorganic filler in the thermosetting resin composition contained in the second region is not particularly limited, and is preferably 2% to 40% by volume, more preferably 10% to 30% by volume, and still more preferably 15% to 25% by volume from the viewpoint of further improving the warpage change amount and the conductor adhesion of the semiconductor package.

The third thermosetting resin composition may or may not contain the inorganic filler, and the suitable content in the case of containing the inorganic filler is the same as the suitable volume-based content range of the inorganic filler in the thermosetting resin composition contained in the first region.

### (Curing Accelerator)

Examples of the curing accelerator include acidic catalysts such as p-toluenesulfonic acid; amine compounds such as triethylamine, tributylamine, pyridine, and dicyandiamide; imidazole compounds such as methylimidazole, phenylimidazole, 2-heptadecylimidazole, 1-cyanoethyl-2-phenylimidazole, and 1-cyanoethyl-2-phenylimidazolium trimellitate; isocyanate-masked imidazole compounds such as an addition reaction product of hexamethylene diisocyanate resin and 2-ethyl-4-methylimidazole; quaternary ammonium compounds; phosphorus-based compounds such as triphenylphosphine; organic peroxides such as dicumyl peroxide, 2,5-dimethyl-2,5-bis(t-butylperoxy) hexyne-3,2,5-dimethyl-2,5-bis(t-butylperoxy) hexane, t-butylperoxyisopropyl monocarbonate, and α,α′-bis(t-butylperoxy) diisopropylbenzene; and carboxylates of manganese, cobalt, and zinc. Among these, imidazole compounds are preferable from the viewpoint of the curing accelerating effect and the storage stability.

When the thermosetting resin composition contains a curing accelerator, the content of the curing accelerator is not particularly limited, and is preferably 0.01 to 5 parts by mass, more preferably 0.05 to 3 parts by mass, and still more preferably 0.1 to 1 part by mass with respect to 100 parts by mass of the thermosetting resin from the viewpoint of the curing accelerating effect and the storage stability.

The content of the solid content derived from the thermosetting resin composition in the prepreg of the present embodiment is not particularly limited, and is preferably 20 to 80 mass %, more preferably 25 to 70 mass %, and still more preferably 30 to 60 mass %.

### <Fiber Base Material>

Examples of the material of the fiber base material include natural fibers such as paper and cotton linter; inorganic fibers such as glass fiber and asbestos; organic fibers such as aramid, polyimide, polyvinyl alcohol, polyester, tetrafluoroethylene, and acryl; and mixtures thereof. Among these, from the viewpoint of flame retardancy, inorganic fibers are preferable, and glass fiber is more preferable.

Examples of the glass fiber include glass fibers using E-glass, C-glass, D-glass, or S-glass.

The material of the fiber base material may be one kind alone or may be a combination of two or more kinds thereof.

Examples of the shape of the fiber base material include shapes such as a woven fabric, a nonwoven fabric, a roving, a chopped strand mat, and a surfacing mat. Among these, a woven fabric is preferable.

Among the above options, glass cloth is preferable as the fiber base material from the viewpoint of low thermal expansion, flame retardancy, and versatility.

The fiber base material may be a single-layered fiber base material or may be a multi-layered fiber base material. The single-layered fiber base material means a fiber base material consisting only of entangled fibers, and in a case where there is a fiber base material without entanglement, it is classified as a multi-layered fiber base material. The material and the shape of the fiber base material of two or more layers may be the same as or different from each other.

The thickness of the fiber base material is not particularly limited and may be appropriately determined depending on the use, and is preferably 10 to 150 μm, more preferably 20 to 100 μm, and still more preferably 30 to 60 μm.

### [Laminated Plate]

A laminated plate of the present embodiment is a laminated plate having a cured product of the prepreg of the present embodiment and a metal foil.

The laminated plate having a metal foil may also be referred to as a metal clad laminate.

The metal of the metal foil is not particularly limited, and examples thereof include copper, gold, silver, nickel, platinum, molybdenum, ruthenium, aluminum, tungsten, iron, titanium, chromium, and an alloy containing one or more kinds of these metal elements.

The laminated plate of the present embodiment can be produced, for example, by disposing a metal foil on one side or both sides of the prepreg of the present embodiment, and then subjecting the prepreg to heating and press molding.

Usually, the B-staged prepreg is cured by this heating and press molding to obtain the laminated plate of the present embodiment.

When the heating and press molding is performed, only one prepreg may be used, or two or more prepregs may be laminated. When two or more prepregs are laminated, it is preferable that at least one surface of an insulating layer included in the laminated plate to be obtained is composed of a cured product of the first region.

For the heating and press molding, for example, a multi-stage press, a multi-stage vacuum press, a continuous molding, or an autoclave molding machine can be used.

The conditions of the heating and press molding are not particularly limited, and the temperature may be 100 to 300° C., the time may be 10 to 300 minutes, and the pressure may be 1.5 to 5 MPa, for example.

### [Printed Wiring Board]

The printed wiring board of the present embodiment is a printed wiring board having a cured product of the prepreg of the present embodiment.

The printed wiring board of the present embodiment can be produced by, for example, forming a conductor circuit on the cured product of the prepreg of the present embodiment by a known method. The surface on which the conductor circuit is formed is preferably a surface composed of the cured product of the first region of the prepreg of the present embodiment.

In addition, a multilayer printed wiring board can also be produced by further performing a multilayer adhesion process as necessary. The conductor circuit can be formed by, for example, appropriately performing a drilling process, a metal plating process, etching of a metal foil, or the like.

### [Semiconductor Package]

The semiconductor package of the present embodiment is a semiconductor package having the printed wiring board of the present embodiment and a semiconductor element.

The semiconductor package of the present embodiment can be produced, for example, by mounting a semiconductor element on the printed wiring board of the present embodiment by a known method. The surface on which the semiconductor element is mounted is preferably a surface composed of the cured product of the first region of the prepreg of the present embodiment or a surface where the conductor circuit has been formed on the above surface.

### EXAMPLES

Hereinafter, the present embodiment will be specifically described with reference to Examples. However, the present embodiment is not limited to the following Examples.

### [Method for Measuring 40° C. and 260° C. Storage Elastic Moduli E′ of Cured Product of Thermosetting Resin Composition]

Copper foils were disposed on both sides of the resin film obtained in each example, and this was pressed using a molding press machine under conditions of a pressure of 1.0 MPa and a maximum holding temperature of 240° C. for 85 minutes to cure the resin film, thereby obtaining a resin plate with copper foils on both sides. The obtained resin plate with copper foils on both sides was immersed in an etching solution to remove the copper foils on both sides and cut into 5 mm×40 mm to produce a test piece. Using the test piece as a measurement target, the storage elastic moduli E′ were measured under conditions of a measurement temperature range of 30° C. to 350° C., a heating rate of 5° C./min, and a frequency of 10 Hz using a dynamic viscoelasticity measuring apparatus (manufactured by UBM, trade name “Rheogel-E4000”), and the storage elastic moduli E′ at 40° C. and 260° C. were acquired.

### [Synthesis of Modified Maleimide Resin]

### Synthesis Example 1

Into a reaction vessel equipped with a thermometer, a stirrer, and a reflux cooling tube, capable of heating and cooling and having a volume of 1 L, 19.4 g of a polydimethyl siloxane compound having primary amino groups at both terminals (manufactured by Dow Corning Toray Co., Ltd., trade name: “X-22-161A”, primary amino group equivalent: 800 g/mol), 13.0 g of 3,3′-diethyl-4,4′-diaminodiphenylmethane, 122.9 g of 4,4′-bismaleimidediphenylmethane, 4.7 g of p-aminophenol, and 240.0 g of propylene glycol monomethyl ether were injected reacted at 115° C. and concentrated at normal pressure so that the resin concentration reached 60 mass %. Further, 53.3 g of cyclohexanone was added at 90° C., and the mixture was stirred for 30 minutes, thereby obtaining a solution of a modified maleimide resin.

### [Production of Resin Varnish]

### Production Example 1

### (Resin Varnish 1)

After 300 parts by mass of the solution of the modified maleimide resin obtained in Synthesis Example 1 in terms of solid content, 170 parts by mass of spherical silica (average particle diameter (D₅₀): 0.25 μm, surface-treated product with 3-aminopropyltrimethoxysilane), 1.2 parts by mass of 2-heptadecylimidazole (manufactured by Shikoku Chemicals Corporation, trade name “C17Z”), and 65 parts by mass of biphenyl aralkyl novolac type epoxy resin (manufactured by Nippon Kayaku Co., Ltd., trade name “NC-3000-H”) were blended together with methyl ethyl ketone, the mixture was stirred and mixed while being heated at 25° C. or 50° C. to 80° C., thereby preparing a resin varnish 1 having a solid content concentration of about 65 mass %.

The volume-based content of the spherical silica with respect to the total amount of the solid content of the resin varnish 1 is 30% by volume.

### Production Example 2

### (Resin Varnish 2)

A resin varnish 2 having a solid content concentration of about 65 mass % was prepared in the same manner as in Production Example 1 except that the amount of the spherical silica blended was changed to 400 parts by mass in Production Example 1.

The volume-based content of the spherical silica with respect to the total amount of the solid content of the resin varnish 2 is 50% by volume.

### [Production of Resin Film, Prepreg, and Copper-Clad Laminated Plate]

### Examples 1 to 3 and Comparative Examples 1 to 3

### (1) Production of Resin Film

Each of the resin varnishes 1 and 2 obtained above was applied onto one surface of a 50 μm-thick PET film. Thereafter, the resin varnish was heated and dried at 125° C. for 3 minutes, thereby forming a resin film made of a thermosetting resin composition on a PET film and obtaining a resin film with the PET film.

Hereinafter, the resin film formed from the resin varnish 1 will be referred to as “low elasticity resin film A”, and the resin film formed from the resin varnish 2 will be referred to as “high elasticity resin film B”. As the low elasticity resin film A and the high elasticity resin film B, films each having a thickness of 8 μm, 10 μm, or 12 μm were produced.

### (2) Bonding of Resin Films

The low elasticity resin film A with the PET film and the high elasticity resin film B with the PET film obtained above were laminated so that the resin films came into contact with each other, and were bonded using a roll laminator while being heated at 100° C. Similarly, the low elasticity resin films A with the PET film and the high elasticity resin films B with the PET film were bonded to each other, thereby obtaining six resin films with the PET films on both sides having the following configurations.
Resin film AB1 with PET films on both sides: Having a laminate structure of PET film/low elasticity resin film A (thickness: 10 μm)/high elasticity resin film B (thickness: 10 μm)/PET film in order.
Resin film AB2 with PET films on both sides: Having a laminate structure of PET film/low elasticity resin film A (thickness: 8 μm)/high elasticity resin film B (thickness: 12 μm)/PET film in order.
Resin film AB3 with PET films on both sides: Having a laminate structure of PET film/low elasticity resin film A (thickness: 12 μm)/high elasticity resin film B (thickness: 8 μm)/PET film in order.
Resin film AA with PET films on both sides: Having a laminate structure of PET film/low elasticity resin film A (thickness: 10 μm)/low elasticity resin film A (thickness: 10 μm)/PET film in order.
Resin film BB with PET films on both sides: Having a laminate structure of PET film/high elasticity resin film B (thickness: 10 μm)/high elasticity resin film B (thickness: 10 μm)/PET film in order.

### (3) Production of Prepreg

The resin film obtained above was laminated on a glass cloth so as to have a configuration of an outer region (11)/an inner region (21)/an inner region (22)/an outer region (12) as shown in FIG. 8, thereby producing a prepreg (thickness: 60 μm). The resin film used for forming each region is shown in Table 1. In addition, a specific production procedure is as follows.

The thicknesses of the outer region (11), the outer region (12), and the inner regions (21) and (22) shown in Table 1 are thicknesses including the glass cloth when the glass cloth is included in the region.

### Example 1

Two sheets of the resin film were prepared, which, from resin films AB1 with the PET films on both sides, the PET films on the side where the high elasticity resin film B was to be exposed were peeled off and removed. Next, on both sides of an E glass cloth having a thickness of 0.04 mm, the exposed high elasticity resin films B were overlaid respectively so as to come into contact with the glass cloth and laminated using a roll laminator while being heated at 130° C., and the PET films on both sides were peeled off, thereby obtaining a prepreg. The content of the solid content derived from the thermosetting resin composition in the obtained prepreg was 40 mass %.

### Example 2

A prepreg was produced by the same procedure as in Example 1 except that the resin films to be laminated on both sides of the glass cloth were changed to the resin films AB2 with the PET films on both sides in Example 1. The content of the solid content derived from the thermosetting resin composition in the obtained prepreg was 39 mass %.

### Example 3

A prepreg was produced by the same procedure as in Example 1 except that the resin films to be laminated on both sides of the glass cloth were changed to the resin films AB3 with the PET films on both sides in Example 1. The content of the solid content derived from the thermosetting resin composition in the obtained prepreg was 41 mass %.

### Comparative Example 1

A prepreg was produced by the same procedure as in Example 1 except that the resin films to be laminated on both sides of the glass cloth were changed to the resin films BB with the PET films on both sides in Example 1. The content of the solid content derived from the thermosetting resin composition in the obtained prepreg was 34 mass %.

### Comparative Example 2

A prepreg was produced by the same procedure as in Example 1 except that the resin films to be laminated on both sides of the glass cloth were changed to the resin films AA with the PET films on both sides in Example 1. The content of the solid content derived from the thermosetting resin composition in the obtained prepreg was 47 mass %.

### Comparative Example 3

Two sheets of the resin film were prepared, which, from resin films AB1 with the PET films on both sides, the PET films on the side where the low elasticity resin film A was to be exposed were peeled off and removed. Next, on both sides of the glass cloth, the exposed low elasticity resin films A were overlaid respectively so as to come into contact with the glass cloth and laminated under the same conditions as in Example 1, thereby producing a prepreg. The content of the solid content derived from the thermosetting resin composition in the obtained prepreg was 40 mass %.

### (4) Production of Double-Sided Copper-Clad Laminated Plate

Next, a double-sided copper-clad laminated plate was produced using the prepreg obtained in each example.

Eight prepregs obtained in each example were overlaid, and an electrolytic copper foil having a thickness of 12 μm was disposed so that an M surface came into contact with the prepreg. This laminated body was subjected to heating and press molding under conditions of a temperature of 240° C., a pressure of 3.0 MPa, and a time of 85 minutes to produce a double-sided copper-clad laminated plate (thickness: about 0.5 mm).

### [Evaluation Methods]

Using the double-sided copper-clad laminated plate obtained in each example, each evaluation was performed according to the following method. The results are shown in Table 1.

### (Methods for Measuring Coefficient of Thermal Expansion and Glass Transition Temperature)

The copper foils on both sides of the double-sided copper-clad laminated plate obtained in each example were removed by etching to produce a 5 mm×5 mm evaluation substrate. Next, thermomechanical analysis was performed by a compression method using a thermomechanical measuring apparatus (TMA) (manufactured by TA Instruments Japan, trade name “Q400”). After the evaluation substrate was mounted on the apparatus, the coefficient of thermal expansion was continuously measured twice under measurement conditions of a heating temperature of 10° C./min. The coefficient of thermal expansion was the coefficient of thermal expansion in the surface direction of the laminated plate, and the average coefficient of thermal expansion in a temperature range of 25° C. to 120° C. and the average coefficient of thermal expansion at 250° C. to 280° C. in the second measurement were each acquired.

### (Method for Measuring 40° C. Storage Elastic Modulus E′)

The copper foils on both sides of the double-sided copper-clad laminated plate obtained in each example were removed by etching to produce a test piece cut into 5 mm×40 mm. Using the test piece as a measurement target, the 40° C. storage elastic modulus E′ was measured under the same conditions as in the [method for measuring storage elastic modulus E′ of cured product of thermosetting resin composition].

### (Method for Measuring Copper Foil Peel Strength)

The copper foils of the double-sided copper-clad laminated plate obtained in each example were processed by etching into a straight line shape having a width of 3 mm and used as a test piece. The formed straight line-shaped copper foil was attached to a compact desktop tester (manufactured by Shimadzu Corporation, trade name: “EZ-TEST”), and the copper foil peel strength was measured by peeling in a 90° direction at room temperature (25° C.). The pulling speed for peeling the copper foil was 50 mm/min.

### (Method for Measuring Warpage Change Amount)

The copper foils on both sides of the double-sided copper-clad laminated plate obtained in each example were removed by etching to produce a substrate cut into 40 mm×40 mm.

A 25 mm×25 mm silicon chip was disposed at the center of one surface of the substrate, and a liquid sealing material (manufactured by Showa Denko K.K., trade name “CEL-C-3730 Series”) was filled into the gap between the substrate and the silicon chip and heated at 140° C. for 3 hours, thereby curing the liquid sealing material to seal the gap. The silicon chip-mounted substrate thus obtained was used as a semiconductor package for measuring the warpage change amount.

Using the semiconductor package obtained above as a measurement target, the temperature-dependent warpage change amount was measured by a shadow moire method using a warpage measuring apparatus equipped with a heating mechanism manufactured by Akrometrix, trade name “TherMoiré P200”. Specifically, a treatment of heating the test piece from 25° C. to 260° C. and then naturally cooling the test piece to room temperature was repeated twice, and the absolute value of the difference between the warpage amount at 25° C. and the warpage amount at 260° C. in the second treatment was regarded as the warpage change amount.

TABLE 1

| | | Examples | | |
|---|---|---|---|---|
| | | 1 | 2 | 3 |
| Configuration of | Resin film used for forming outer region | Low | Low | Low |
| prepreg | (11) | elasticity | elasticity | elasticity |
| (FIG. 8) | | resin film A | resin film A | resin film A |
| | Resin film used for forming inner region | High | High | High |
| | (21) | elasticity | elasticity | elasticity |
| | | resin film B | resin film B | resin film B |
| | Resin film used for forming inner region | High | High | High |
| | (22) | elasticity | elasticity | elasticity |
| | | resin film B | resin film B | resin film B |
| | Resin film used for forming outer region | Low | Low | Low |
| | (12) | elasticity | elasticity | elasticity |
| | | resin film A | resin film A | resin film A |
| Physical properties | 260° C. storage elastic moduli E′ (i) (GPa) of | 0.6 | 0.6 | 0.6 |
| of outer regions | cured product of thermosetting resin | | | |
| (11) and (12) of | composition contained in outer regions (11) | | | |
| prepreg | and (12) | | | |
| | 40° C. storage elastic moduli E′ (GPa) of | 4.6 | 4.6 | 4.6 |
| | cured product of thermosetting resin | | | |
| | composition contained in outer regions (11) | | | |
| | and (12) | | | |
| | Content V (i) (% by volume) of the | 30 | 30 | 30 |
| | inorganic filler in thermosetting resin | | | |
| | composition contained in outer regions (11) | | | |
| | and (12) | | | |
| | Thickness of outer region (11) (μm) | 10 | 8 | 12 |
| | Thickness of outer region (12) (μm) | 10 | 8 | 12 |
| Physical properties | 260° C. storage elastic moduli E′ (ii) (GPa) | 1.1 | 1.1 | 1.1 |
| of inner regions | of cured product of thermosetting resin | | | |
| (21) and (22) of | composition contained in inner regions (21) | | | |
| prepreg | and (22) | | | |
| | 40° C. storage elastic moduli E′ (GPa) of | 5.6 | 5.6 | 5.6 |
| | cured product of thermosetting resin | | | |
| | composition contained in inner regions (21) | | | |
| | and (22) | | | |
| | Content V (ii) (% by volume) of the | 50 | 50 | 50 |
| | inorganic filler in thermosetting resin | | | |
| | composition contained in inner regions (21) | | | |
| | and (22) | | | |
| | Thickness of inner region (21) (μm) | 20 | 22 | 18 |
| | Thickness of inner region (22) (μm) | 20 | 22 | 18 |
| Difference [E′ (ii) − E′ (i)] (GPa) between 260° C. storage elastic | | 0.5 | 0.5 | 0.5 |
| modulus E′ (i) and 260° C. storage elastic modulus E′ (ii) | | | | |
| Difference [V (ii) − V (i)] (% by volume) between content V (i) of | | 20 | 20 | 20 |
| inorganic filler and content V (ii) of inorganic filler | | | | |
| Evaluation results | Average coefficient of thermal expansion | 10.3 | 10.1 | 10.5 |
| | (25° C.-120° C.) (ppm/° C.) | | | |
| | Average coefficient of thermal expansion | 12.4 | 12.5 | 12.6 |
| | (250° C.-280° C.) (ppm/° C.) | | | |
| | Glass transition temperature (° C.) | 209 | 211 | 208 |
| | 40° C. storage elastic modulus E′ (GPa) | 12.0 | 12.5 | 11.4 |
| | Copper foil peel strength (kN/m) | 0.66 | 0.65 | 0.65 |
| | Warpage change amount (μm) | 325 | 323 | 327 |
| | | Comparative Example | | |
| | | 1 | 2 | 3 |
| Configuration of | Resin film used for forming outer region | High | Low | High |
| prepreg | (11) | elasticity | elasticity | elasticity |
| (FIG. 8) | | resin film B | resin film A | resin film B |
| | Resin film used for forming inner region | High | Low | Low |
| | (21) | elasticity | elasticity | elasticity |
| | | resin film B | resin film A | resin film A |
| | Resin film used for forming inner region | High | Low | Low |
| | (22) | elasticity | elasticity | elasticity |
| | | resin film B | resin film A | resin film A |
| | Resin film used for forming outer region | High | Low | High |
| | (12) | elasticity | elasticity | elasticity |
| | | resin film B | resin film A | resin film B |
| Physical properties | 260° C. storage elastic moduli E′ (i) (GPa) of | 1.1 | 0.6 | 1.1 |
| of outer regions | cured product of thermosetting resin | | | |
| (11) and (12) of | composition contained in outer regions (11) | | | |
| prepreg | and (12) | | | |
| | 40° C. storage elastic moduli E′ (GPa) of | 5.6 | 4.6 | 5.6 |
| | cured product of thermosetting resin | | | |
| | composition contained in outer regions (11) | | | |
| | and (12) | | | |
| | Content V (i) (% by volume) of the | 50 | 30 | 50 |
| | inorganic filler in thermosetting resin | | | |
| | composition contained in outer regions (11) | | | |
| | and (12) | | | |
| | Thickness of outer region (11) (μm) | 10 | 10 | 10 |
| | Thickness of outer region (12) (μm) | 10 | 10 | 10 |
| Physical properties | 260° C. storage elastic moduli E′ (ii) (GPa) | 1.1 | 0.6 | 0.6 |
| of inner regions | of cured product of thermosetting resin | | | |
| (21) and (22) of | composition contained in inner regions (21) | | | |
| prepreg | and (22) | | | |
| | 40° C. storage elastic moduli E′ (GPa) of | 5.6 | 4.6 | 4.6 |
| | cured product of thermosetting resin | | | |
| | composition contained in inner regions (21) | | | |
| | and (22) | | | |
| | Content V (ii) (% by volume) of the | 50 | 30 | 30 |
| | inorganic filler in thermosetting resin | | | |
| | composition contained in inner regions (21) | | | |
| | and (22) | | | |
| | Thickness of inner region (21) (μm) | 20 | 20 | 20 |
| | Thickness of inner region (22) (μm) | 20 | 20 | 20 |
| Difference [E′ (ii) − E′ (i)] (GPa) between 260° C. storage elastic | | 0 | 0 | −0.5 |
| modulus E′ (i) and 260° C. storage elastic modulus E′ (ii) | | | | |
| Difference [V (ii) − V (i)] (% by volume) between content V (i) of | | 0 | 0 | −20 |
| inorganic filler and content V (ii) of inorganic filler | | | | |
| Evaluation results | Average coefficient of thermal expansion | 9.8 | 11.3 | 11.0 |
| | (25° C.-120° C.) (ppm/° C.) | | | |
| | Average coefficient of thermal expansion | 13.0 | 13.1 | 14.0 |
| | (250° C.-280° C.) (ppm/° C.) | | | |
| | Glass transition temperature (° C.) | 217 | 204 | 208 |
| | 40° C. storage elastic modulus E′ (GPa) | 13.5 | 9.2 | 10.3 |
| | Copper foil peel strength (kN/m) | 0.57 | 0.67 | 0.54 |
| | Warpage change amount (μm) | 349 | 388 | 367 |

From the results shown in Table 1, it can be seen that the copper-clad laminated plates formed from the prepregs of Examples 1 to 3 of the present embodiment have a high copper foil peel strength, and the semiconductor packages for which the copper-clad laminated plates are used have a small warpage change amount. On the other hand, the semiconductor packages for which the copper-clad laminated plates formed of the prepregs of Comparative Examples 1 to 3 were used had a large warpage change amount, and the copper-clad laminated plates formed from the prepregs of Comparative Examples 1 and 3 had a low copper foil peel strength.

### REFERENCE SIGNS LIST

10, 20, 20a, 20b, 30, 30a, 30b Prepreg
1 First region
2 Second region
3 Third region
4 Fiber base material
1a Resin layer (first region)
2a Composite layer (second region)
1b Resin layer (first region)
2b Composite layer (second region)
1a′ First resin layer (first region)
2a′ Second resin layer (second region)
3a′ Composite layer (third region)
1b′ Resin layer (first region)
2b′ Second composite layer (second region)
3b′ First composite layer (third region)
(11) Outer region
(12) Outer region
(21) Inner region
(22) Inner region
Sα, Sβ Surface of prepreg
S2α, S2β Surface of second region
S3α, S3β Surface of third region
S4α, S4β Surface of fiber base material
X, X1, X2 Direction

1. A prepreg comprising:
a thermosetting resin composition; and
a fiber base material,
wherein the prepreg has one surface and other surface opposite to the one surface,
in a direction from at least any surface of the one surface and the other surface as a starting point toward a surface opposite to the surface serving as the starting point, the prepreg has, in the following order,
a first region that configures the surface of the prepreg serving as the starting point and is a region containing a thermosetting resin composition, and
a second region that is a region containing a thermosetting resin composition different from the thermosetting resin composition contained in the first region, and
a storage elastic modulus E′(1) at 260° C. of a cured product of the thermosetting resin composition contained in the first region is lower than a storage elastic modulus E′(2) at 260° C. of a cured product of the thermosetting resin composition contained in the second region.

2. The prepreg according to claim 1,
wherein, in a direction from each of the one surface and the other surface as a starting point toward a surface opposite to the surface serving as the starting point, the prepreg has the first region and the second region in this order.

3. The prepreg according to claim 1,
wherein a difference [E′(2)−E′(1)] between the storage elastic modulus E′(1) at 260° C. of the cured product of the thermosetting resin composition contained in the first region and the storage elastic modulus E′(2) at 260° C. of the cured product of the thermosetting resin composition contained in the second region is 0.05 to 1.5 GPa.

4. The prepreg according to claim 1,
wherein the storage elastic modulus E′(1) at 260° C. of the cured product of the thermosetting resin composition contained in the first region is 0.1 to 1.5 GPa.

5. The prepreg according to claim 1,
wherein the storage elastic modulus E′(2) at 260° C. of the cured product of the thermosetting resin composition contained in the second region is 0.5 to 2.0 GPa.

6. The prepreg according to claim 1,
wherein the thermosetting resin composition contained in the first region and the thermosetting resin composition contained in the second region contain an inorganic filler, and
a volume-based content V(1) of the inorganic filler in the thermosetting resin composition contained in the first region is lower than a volume-based content V(2) of the inorganic filler in the thermosetting resin composition contained in the second region.

7. The prepreg according to claim 6,
wherein a difference [V(2)−V(1)] between the volume-based content V(1) of the inorganic filler in the thermosetting resin composition contained in the first region and the volume-based content V(2) of the inorganic filler in the thermosetting resin composition contained in the second region is 2% to 40% by volume.

8. The prepreg according to claim 1,
wherein the volume-based content V(1) of the inorganic filler in the thermosetting resin composition contained in the first region is 5% to 60% by volume.

9. The prepreg according to claim 1,
wherein the volume-based content V(2) of the inorganic filler in the thermosetting resin composition contained in the second region is 20% to 80% by volume.

10. A laminated plate comprising:
a cured product of the prepreg according to claim 1; and
a metal foil.

11. A printed wiring board comprising:
a cured product of the prepreg according to claim 1.

12. A semiconductor package comprising:
the printed wiring board according to claim 11; and
a semiconductor element.
